(19) United States
(12) Patent Application Publication
(10) Pub. No.: US 2025/0259945 A1
(43) Pub. Date: Aug. 14, 2025

(54) SACRIFICIAL PLATE INSERT FOR RIGID-CORE LAMINATE TOOLING-HOLE DRILLING

(71) Applicant: Qorvo US, Inc., Greensboro, NC (US)

(72) Inventors: Matthew Irvine, Garland, TX (US); Anthony Chiu, Richardson, TX (US); Andrew Arthur Ketterson, Dallas, TX (US)

(21) Appl. No.: 19/009,312

(22) Filed: Jan. 3, 2025

Related U.S. Application Data
(60) Provisional application No. 63/551,858, filed on Feb. 9, 2024.

(51) Int. Cl. H01L 23/00; H01L 21/48; H01L 23/13; H01L 23/498

(52) U.S. Cl. CPC H01L 23/562; H01L 21/4857; H01L 23/13; H01L 23/49822

(57) ABSTRACT

The present disclosure relates to a rigid-core laminate that includes a core section formed of a first material with a first modulus of at least 50 GPa, a number of sacrificial sockets embedded in the core section through a potting material, a number of top dielectric layers formed over a top surface of the core section and covering a top surface of each sacrificial socket, a number of bottom dielectric layers formed underneath a bottom surface of the core section and covering a bottom surface of each sacrificial socket, and a number of tooling-holes. Herein, each sacrificial socket is formed of a second material with a second modulus that is smaller than the first modulus. Each tooling-hole extends vertically through the top dielectric layers, a corresponding sacrificial socket, and the bottom dielectric layers. No portion of the core section is exposed in any one of the tooling-holes.

### RELATED APPLICATIONS

This application claims the benefit of provisional patent application Ser. No. 63/551,858, filed Feb. 9, 2024, the disclosure of which is hereby incorporated herein by reference in its entirety.

### FIELD OF THE DISCLOSURE

The present disclosure relates to a rigid-core laminate with tooling-holes that are formed by drilling/milling through sacrificial plates embedded in a rigid-core section of the rigid-core laminate.

### BACKGROUND

As microelectronics continue to miniaturize and handle higher powers and frequencies, new package substrates are constantly being introduced to integrated circuit applications. One of the new players in the industry is glass-core laminates. Moving from traditional composite core laminates to the glass-core laminates enables rigid interposers with dimensional stability and finer line/space and offers the ability to embed electronic components within the laminates. Other types of ceramic materials may also be desired materials used for the rigid core portions of laminates.

However, these ceramic-core laminates are not easy to drill through once they have been manufactured with patterned copper traces. Due to the brittle characteristics of the rigid core materials, drilling can thus be destructive and cause cracks in the core of these laminates. On the other hand, overmolding laminates in packaging processes typically requires the utilization of alignment pins, which need tooling-holes to be held in place. Although other works apply compression molding instead of overmolding to avoid drilling holes, compression molding is costly. In addition, even if tooling-holes may be formed through the rigid-core laminates, the core material (e.g., glass) exposed in the tooling-holes is susceptible to damage by anything that would be inserted into the tooling-holes (e.g., the alignment pins).

Accordingly, there remains a need for improved laminate designs, which would enable tooling-hole drilling so as to accommodate alignment pins for overmolding. In addition, there is also a desire that the interior of the tooling-hole is soft and firm enough to be capable of handling tensile stresses much better than these rigid core materials.

### SUMMARY

The present disclosure relates to a rigid-core laminate with tooling-holes that are formed by drilling/milling through sacrificial plates embedded in a rigid-core section of the rigid-core laminate. The disclosed rigid-core laminate includes a core section formed of a first material with a first modulus of at least 50 GPa, a number of sacrificial sockets embedded in the core section through a potting material, a number of top dielectric layers formed over a top surface of the core section and covering a top surface of each of the sacrificial sockets, a number of bottom dielectric layers formed underneath a bottom surface of the core section and covering a bottom surface of each of the sacrificial sockets, and a number of tooling-holes. Herein, each sacrificial socket is formed of a second material with a second modulus that is smaller than the first modulus. Each tooling-hole extends vertically through the top dielectric layers, a corresponding sacrificial socket within the core section, and the bottom dielectric layers. No portion of the core section is exposed in any one of the tooling-holes. In one embodiment of the rigid-core laminate, the second modulus is

no more than 20 GPa.

In one embodiment of the rigid-core laminate, the first material is a ceramic material.

In one embodiment of the rigid-core laminate, the second material is a polymer material or a polymer and inorganic composite.

In one embodiment of the rigid-core laminate, the core section has a height between 10 μm and 2000 μm. Each top dielectric layer has a thickness between 0.2 μm and 60 μm, and each bottom dielectric layer has a thickness between 0.2 μm and 60 μm.

In one embodiment of the rigid-core laminate, a horizontal shape of each tooling-hole is constant along a vertical direction, which is identical to a shape of an inner perimeter of the corresponding sacrificial socket.

In one embodiment of the rigid-core laminate, the shape of the inner perimeter of each of the sacrificial sockets is a circle, a square, a rectangle, an oval, or a cushion. The shape of the outer perimeter of each of the sacrificial sockets is a circle, a square, a rectangle, an oval, or a cushion.

In one embodiment of the rigid-core laminate, a diameter of the inner perimeter of each of the sacrificial sockets is between 1 mm and 5 mm, and a diameter of the outer perimeter of each of the sacrificial sockets is between 1.1 mm and 5 mm.

According to one embodiment, the rigid-core laminate further includes a number of protective vias. Each sacrificial socket is surrounded by certain ones of the protective vias. Each of the protective vias has a diameter between 100 μm and 150 μm.

According to one embodiment, the rigid-core laminate further includes a number of top metal layers, and a number of bottom metal layers. Herein, the top dielectric layers and the top metal layers are alternately formed over the top surface of the core section. The bottom dielectric layers and the bottom metal layers are alternately formed underneath the bottom surface of the core section.

In one embodiment of the rigid-core laminate, the top dielectric layers and the bottom dielectric layers are formed of a dielectric material, which has a modulus of no more than 15 GPa.

In one embodiment of the rigid-core laminate, the top dielectric layers and the bottom dielectric layers are formed of Ajinomoto build-up film (ABF) epoxy or polyimide.

In one embodiment of the rigid-core laminate, the potting material is epoxy.

According to one embodiment, a method of fabricating a package assembly includes forming a rigid-core laminate. Forming the rigid-core laminate starts with providing a core section with a number of cavities. Next, a sacrificial plate is embedded into each cavity. Herein, the core section is formed of a first material with a first modulus of at least 50 GPa, and the sacrificial plate is formed of a second material with a second modulus that is smaller than the first modulus. A potting material is then applied to fill a gap between the sacrificial plate and a corresponding cavity. After the potting material is applied, a number of top dielectric layers are formed over a top surface of the core section and over a top surface of each sacrificial plate, and a number of bottom dielectric layers are formed underneath a bottom surface of the core section and underneath a bottom surface of each sacrificial plate. Lastly, a tooling-hole is formed where a corresponding sacrificial plate is located. Each tooling-hole has a smaller horizontal size than a diameter of the corresponding sacrificial plate, and each sacrificial plate is converted into a corresponding sacrificial socket. Each tooling-hole extends vertically through the top dielectric layers, the corresponding sacrificial socket, and the bottom dielectric layers.

In one embodiment of the method, the core section further includes a number of hollow protective vias surrounding each cavity.

In one embodiment of the method, forming the rigid-core laminate further includes applying a metal plating step to the core section before forming the plurality of top dielectric layers and the plurality of bottom dielectric layers. Herein, a first top metal layer is formed with a metal material over the top surface of the core section, a first bottom metal layer is formed with the metal material underneath the bottom surface of the core section, and each hollow protective via is filled with the metal material.

In one embodiment of the method, the metal plating step is applied before embedding the sacrificial plate into each of the cavities, such that the metal material extends to cover an interior wall of each of the cavities.

In one embodiment of the method, forming the rigid-core laminate further includes forming a number of top metal layers and a number of bottom metal layers. Herein, the top metal layers and the top dielectric layers are alternately formed over the top surface of the core section, while the bottom metal layers and the bottom dielectric layers are alternately formed underneath the bottom surface of the core section.

In one embodiment of the method, the second modulus is no more than 20 GPa.

In one embodiment of the method, the first material is a ceramic material, and the second material is a polymer material or a polymer and inorganic composite.

In one embodiment of the method, the tooling-hole is formed by a mechanical drill or laser machining.

According to one embodiment, the method further includes attaching one or more electrical devices to the rigid-core laminate. In horizontal dimensions, the rigid-core laminate is divided into a border region and an active region, which is surrounded by the border region. The one or more electrical devices are located on a top surface of the rigid-core laminate and within the active region, while each sacrificial socket and the corresponding tooling-hole are located within the border region.

According to one embodiment, the method further includes inserting one alignment pin into a corresponding tooling-hole and applying a mold compound over the rigid-core laminate. Herein, each alignment pin has a height larger than a height of the rigid-core laminate and protrudes above the top surface of the rigid-core laminate. The mold compound is applied using each alignment pin as a landmark, such that the one or more electrical devices are fully encapsulated by the mold compound.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A-1B show an exemplary rigid-core laminate according to some embodiments of the present disclosure.

FIGS. 2A-7B show an exemplary fabricating process that illustrates steps to provide the exemplary rigid-core laminate shown in FIGS. 1A-1B.

FIGS. 8-10B show an exemplary packaging process that illustrates steps to provide a package assembly formed based on the exemplary rigid-core laminate.

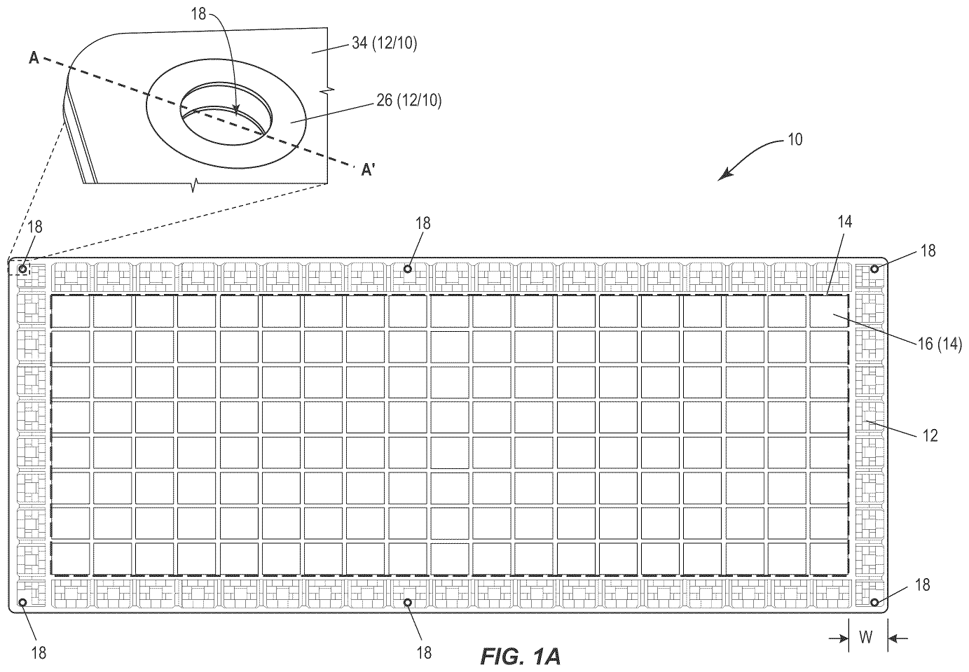

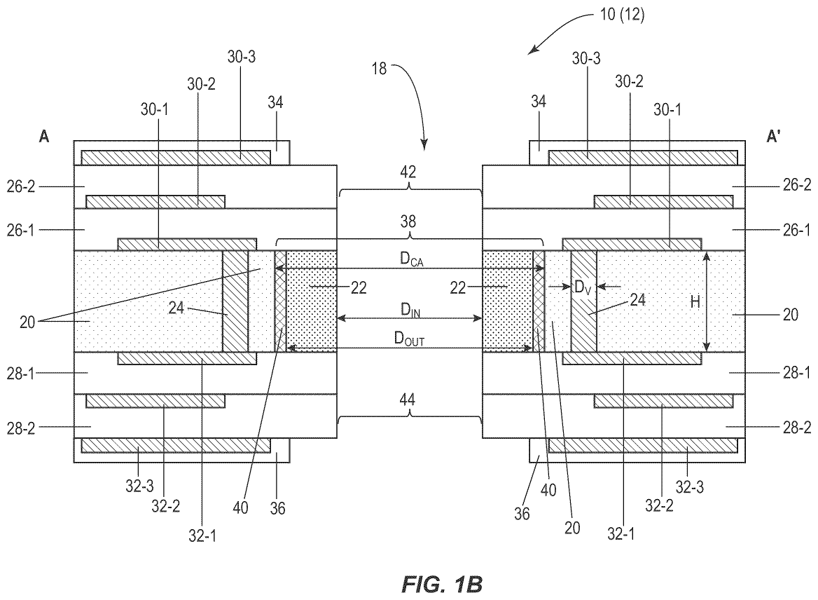

It will be understood that for clear illustrations, FIGS. 1-10B may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

As microelectronics continue to miniaturize and handle higher powers and frequencies, ceramic materials, which enable dimensional stability, finer line/space, and embedded electronic components, attract increasing attention for use in package substrates. FIGS. 1A-1B show an exemplary rigid-core laminate 10 according to some embodiments of the present disclosure.

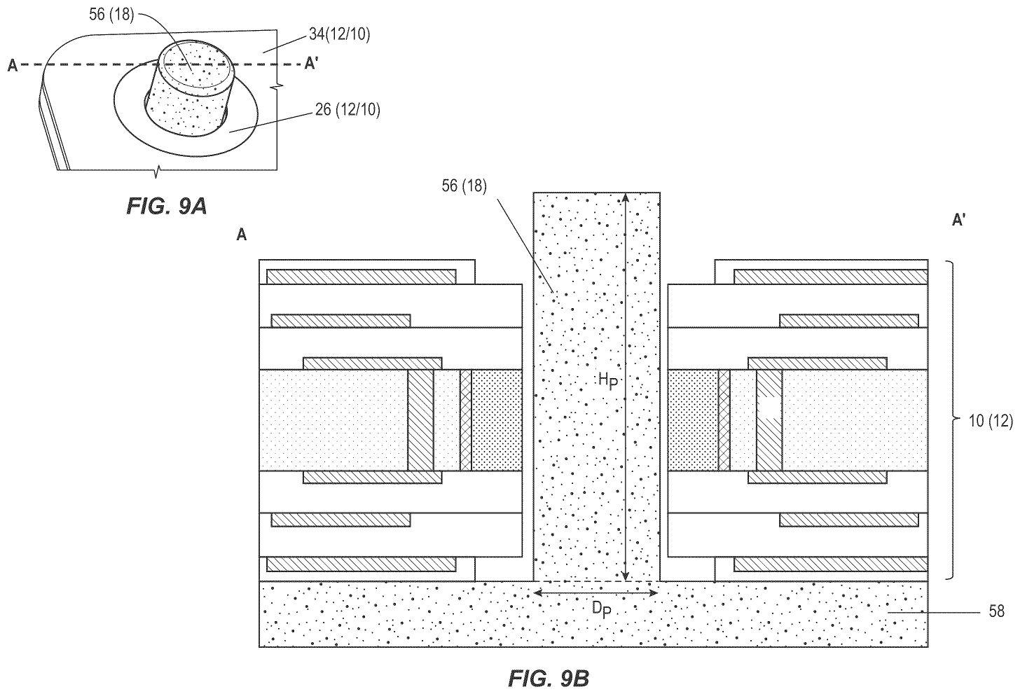

FIG. 1A illustrates a top view of the rigid-core laminate 10, while FIG. 1B illustrates a cross-section view of the rigid-core laminate 10 along a dashed line A-A′ in FIG. 1A. From the top view aspect, the rigid-core laminate 10 can be divided into a border region 12 and an active region 14, which is surrounded by the border region 12 and includes a number of device-attached segments 16 (for clarity, only one device-attached segment is labeled with a reference number). Each device-attached segment 16 is configured to accommodate one or more electronic components (e.g., dies, surface mounted devices, and/or etc.). Within the border region 12, on the other hand, there are no electronic functions (e.g., no electronic components or electronic signal routing paths). For the purpose of this illustration, the border region 12 includes six tooling-holes 18 substantially evenly distributed about a periphery of the border region 12, each of which vertically extends from a top surface of the rigid-core laminate 10 to a bottom surface of the rigid-core laminate 10. The tooling-holes 18 may be configured to hold alignment pins (not shown in FIGS. 1A-1B, see FIGS. 9A-9B) in place to enable a desired overmolding process (more details are described in the following paragraphs). In different applications, the rigid-core laminate 10 may include fewer or more tooling-holes 18 with a different layout in the border region 12, and/or the rigid-core laminate 10 may include tooling-holes 18 within the active region 14 (e.g., horizontally between the device-attached segments 16 or within certain device-attached segments 16). The border region 12 may have a width W between 0.2 mm and 50 mm, or between 1.2 mm and 50 mm.

From the cross-section view aspect, the rigid-core laminate 10 includes a core section 20, sacrificial sockets 22, protective vias 24, top dielectric layers 26, bottom dielectric layers 28, top metal layers 30, bottom metal layers 32, a top solder-mask 34, and a bottom solder-mask 36. In detail, the core section 20 is a rigid section and may be formed of glass, silicon carbide, silicon, aluminum dioxide, aluminum nitride, or other ceramic material, which has a modulus of at least 50 GPa. With the core section 20, the rigid-core laminate 10 is capable of obtaining dimensional stability and finer line/space and capable of allowing embedded electronic components (not shown). Due to different applications, the core section 20 may also be formed of other rigid materials (other than ceramic materials) with a modulus of at least 50 GPa for desired geometric/electronic/thermal performance. In addition, the core section 20 includes multiple cavities 38, each of which extends vertically through the core section 20 and is located where a corresponding tooling-hole 18 is formed. As such, when the tooling-holes 18 are located within the border region 12 of the rigid-core laminate 10, the cavities 38 are also formed around the periphery of the border region 12. Alternatively, when the tooling-holes 18 are located within the active region 14 the rigid-core laminate 10 and the cavities 38 are formed in the active region 14 accordingly. A border region of the core section 20 and an active region of the core section 20 correspond to (e.g., are aligned with) the border region 12 of the rigid-core laminate 10 and the active region 14 of the rigid-core laminate 10, respectively. Each cavity 38 may be confined within the border region of the core section 20 and/or within the active region of the core section 20. The core section 20 may have a height H between 10 μm and 2000 μm, or between 300 μm and 400 μm. Each cavity 38 may have a shape of a circle, a square, a rectangle, an oval, a cushion, or any appropriate shape in a horizontal plane, with a diameter/diagonal D_{CA} between 0.2 mm and 5 mm or between 1.2 mm and 5 mm.

Each sacrificial socket 22 is embedded in a corresponding cavity 38 of the core section 20 and attached to the core section 20 via a potting material 40. The sacrificial sockets 22 may be embedded at the periphery of the border region 12 and/or within the active region 14 due to the locations of the cavities 38. For the purpose of this illustration, an inner perimeter and an outer perimeter of one sacrificial socket 22 are circles. In different applications, the inner perimeter of one sacrificial socket 22 may also be a square, a rectangle, an oval, a cushion, or any appropriate shape. The outer perimeter of one sacrificial socket 22, which is required to be smaller than the corresponding cavity 38 (i.e., the diameter/diagonal D_{CA} of one cavity 38 is larger than an outer diameter/diagonal D_{OUT} of the corresponding sacrificial socket 22 and is certainly larger than an inner diameter/diagonal D_{IN}) and can fit in the corresponding cavity 38, may also be a square, a rectangle, an oval, a cushion, or any appropriate shape. Typically, each cavity 38 may have a same horizontal shape as the outer perimeter of the corresponding sacrificial socket 22 with a small horizontal gap (e.g., 20 μm˜150 μm) for the potting material 40 therebetween. The inner perimeter of the sacrificial socket 22 and the outer perimeter of the sacrificial socket 22 may have different shapes (e.g., the inner perimeter is a circle, while the outer perimeter is a square). Each sacrificial socket 22 may have a height about the same as the core section 20. Herein, each sacrificial socket 22 corresponds to one particular tooling-hole 18, where the inner perimeter of one sacrificial socket 22 defines a horizontal size/shape of the corresponding tooling-hole 18.

In some applications, each cavity 38 may have a same or different shape with same or different dimensions. Each sacrificial socket 22 may have a same or different shape of the inner/outer perimeter with same or different dimensions. In addition, each sacrificial socket 22 may be formed from a same or different material. In some embodiments, the diameter/diagonal DIN of the inner perimeter of the sacrificial socket 22 is between 0.1 mm and 5 mm or between 1 mm and 5 mm, the diameter/diagonal D_{OUT} of the outer perimeter of the sacrificial socket 22 is between 0.2 mm and 5 mm or between 1.1 mm and 5 mm, and the height of one sacrificial socket 22 is substantially the same as the height H of the core section 20. The sacrificial sockets 22 may be formed of polymer, polymer and inorganic composite, or other relatively soft materials that can be readily drilled and serve as a stress buffer between the core section 20 and the alignment pins with a modulus of no more than 20 GPa. Typical materials such as Nylon, polyimide, PEEK are suitable for forming the sacrificial sockets 22. The potting material 40, which is configured to bond the sacrificial sockets 22 to the core section 20, may be an epoxy and fills the gap between each cavity 38 and its corresponding sacrificial socket 22.

In addition, each cavity 38/sacrificial socket 22 may be surrounded by multiple protective vias 24. Each protective via 24 extends vertically through the core section 20 and has a diameter/diagonal D_{V} between 100 μm and 150 μm.

The protective vias 24 are typically plated with a metal material (e.g., copper) and may be filled with a metal or polymer material. The protective vias 20 are configured to act as crack-stops for the corresponding cavity 38 (more details are described in the following paragraphs).

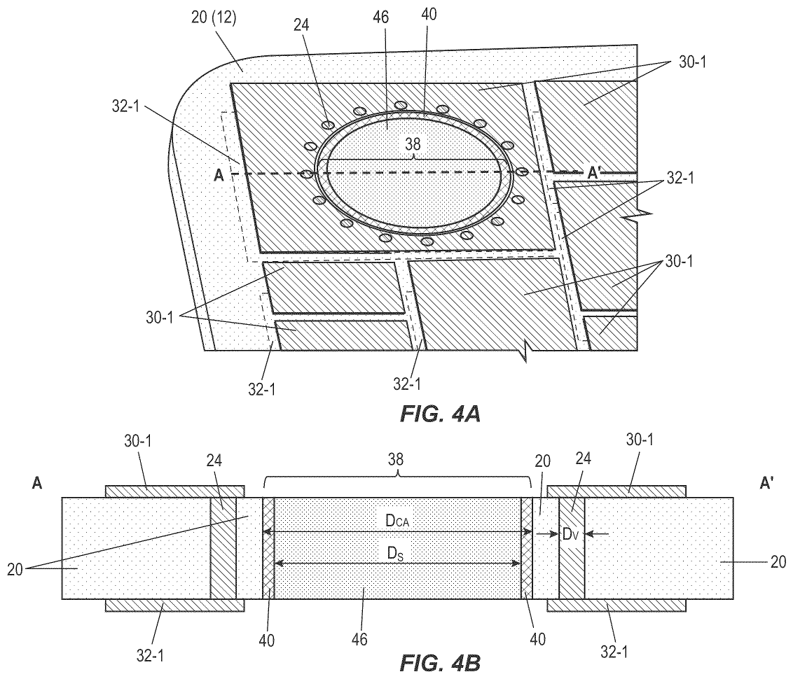

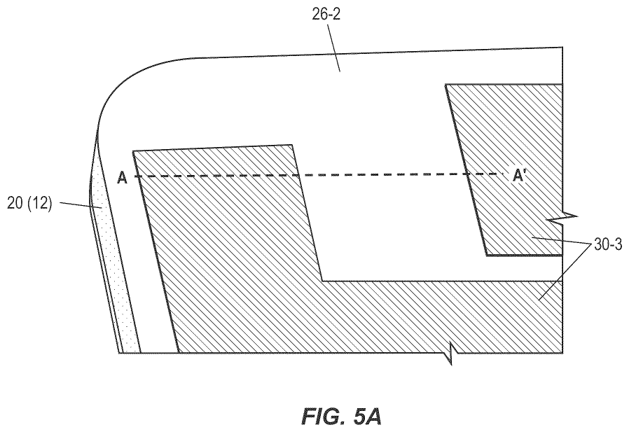

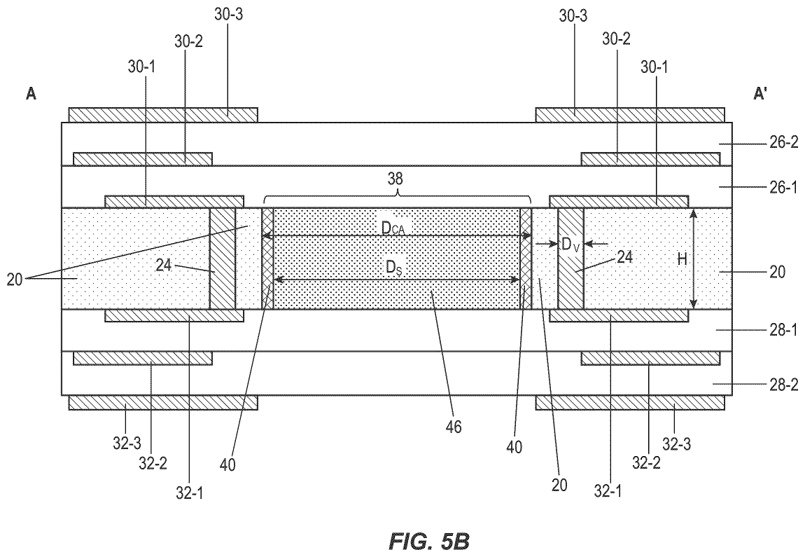

The top dielectric layers 26 (e.g., a first top dielectric layer 26-1 over the core section 20 and a second top dielectric layer 26-2 over the first top dielectric layer 26-1) and the top metal layers 30 (e.g., a first top metal layer 30-1 over the core section 20, a second top metal layer 30-2 over the first top metal layer 30-1, and a third top metal layer 30-3 over the second top metal layer 30-2) are alternately formed over a top surface of the core section 20 (e.g. the first top metal layer 30-1 is formed over the top surface of the core section 20, the first top dielectric layer 26-1 is formed over the top surface of the core section 20 and encapsulates the first top metal layer 30-1, the second top metal layer 30-2 is formed over the first top dielectric layer 26-1, and the second top dielectric layer 26-2 is formed over the first top dielectric layer 26-1 and encapsulates the second top metal layer 30-2, and the third top metal layer 30-3 is formed over the second top dielectric layer 26-2). Each top dielectric layer 26 may have a thickness between 0.2 μm and 60 μm or between 20 μm and 30 μm, and may be formed of a dielectric material, such as Ajinomoto build-up film (ABF) epoxy, polyimide, or other dielectric typically used in the microelectronics industry. The top dielectric layers 26 are relatively soft and may have a modulus of no more than 15 GPa. The top metal layers 30 are separated from each other by the top dielectric layers 26, and may be formed of a conducting material, such as copper or gold. Herein, the top dielectric layers 26 include multiple top holes 42, each of which extends vertically through all of the top dielectric layers 26 and is vertically aligned with the inner perimeter of a corresponding sacrificial socket 22. Each top hole 42 may have an identical horizontal shape and size as the inner perimeter of the corresponding sacrificial socket 22. As such, the top holes 42 may be formed around the periphery of the border region 12 and/or within the active region 14 corresponding to the locations of the sacrificial sockets 22. Each top metal layer 30 may include multiple discrete metal sections (see FIGS. 4A and 5A), is confined within the top dielectric layers 26, and does not extend across any portion of each top hole 42.

Similarly, the bottom dielectric layers 28 (e.g., a first bottom dielectric layer 28-1 underneath the core section 20 and a second bottom dielectric layer 28-2 underneath the first bottom dielectric layer 28-1) and the bottom metal layers 32 (e.g., a first bottom metal layer 32-1 underneath the core section 20, a second bottom metal layer 32-2 underneath the first bottom metal layer 32-1, and a third bottom metal layer 32-3 underneath the second bottom metal layer 32-2) are alternately formed underneath a bottom surface of the core section 20 (e.g.

the first bottom metal layer 32-1 is formed underneath the bottom surface of the core section 20, the first bottom dielectric layer 28-1 is formed underneath the bottom surface of the core section 20 and encapsulates the first bottom metal layer 32-1, the second bottom metal layer 32-2 is formed underneath the first bottom dielectric layer 28-1, and the second bottom dielectric layer 28-2 is formed underneath the first bottom dielectric layer 28-1 and encapsulates the second bottom metal layer 32-2, and the third bottom metal layer 32-3 is formed underneath the second bottom dielectric layer 28-2). Each bottom dielectric layer 28 may have a thickness between 0.2 μm and 60 μm or between 20 μm and 30 μm, and may be formed of a dielectric material, such as ABF epoxy, polyimide, or other dielectric typically used in the microelectronics industry. The bottom dielectric layers 28 are relatively soft and may have a modulus of no more than 15 GPa. The bottom metal layers 32 are separated from each other by the bottom dielectric layers 28, and may be formed of a conducting material, such as copper or gold. Herein, the bottom dielectric layers 28 include multiple bottom holes 44, each of which extends vertically through all of the bottom dielectric layers 28 and is vertically aligned with the inner perimeter of a corresponding sacrificial socket 22. Each bottom hole 44 may have an identical horizontal shape and size as the inner perimeter of the corresponding sacrificial socket 22. As such, the bottom holes 44 may be formed around the periphery of the border region 12 and/or within the active region 14 corresponding to the locations of the sacrificial sockets 22. Each bottom metal layer 32 may include multiple discrete metal sections (see FIG. 4A), is confined with the bottom dielectric layers 28, and does not extend across any portion of each bottom hole 44.

For the purpose of this illustration, the rigid-core laminate 10 includes two top dielectric layers 26, three top metal layers 30, two bottom dielectric layers 28, and three bottom metal layers 32. In different applications, the rigid-core laminate 10 may include fewer or more top dielectric layers 26, fewer or more top metal layers 30, fewer or more bottom dielectric layers 28, and fewer or more bottom metal layers 32. The top dielectric layers 26 may have a total thickness between 0.004 mm and 1 mm, while the bottom dielectric layers 28 may have a total thickness between 0.004 mm and 1 mm.

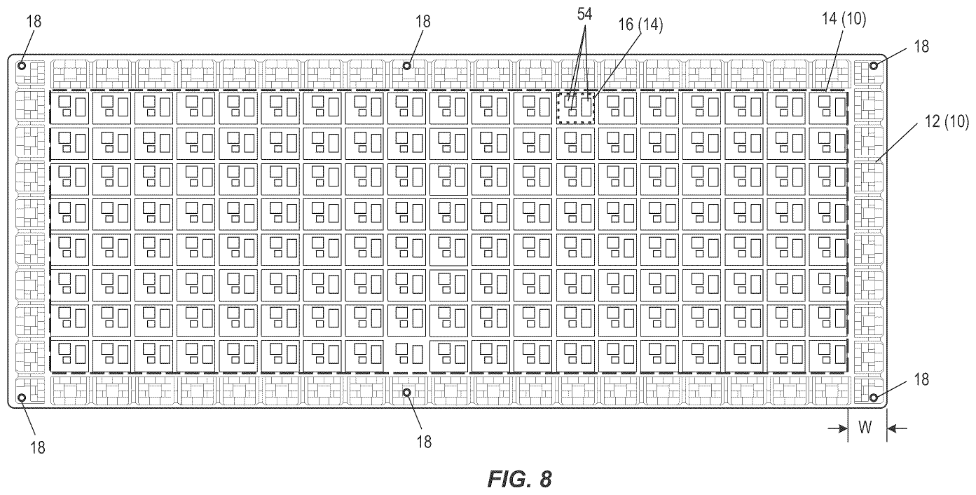

The top metal layers 30 and the bottom metal layers 32 are configured to provide signal paths for devices (see FIG. 8, devices 54) attached to the active region 14. In some embodiments, the protective vias 24 may be connected to one top metal layer 30 and/or one bottom metal layer 32. Regardless of whether the protective vias 24 are connected to the top/bottom metal layers 30/32, the protective vias 24 are not used to transmit any electrical signals. Furthermore, the top solder-mask 34 is formed over the top dielectric layers 26 to protect any top metal layer 30 (e.g., the third top metal layer 30-3) not being encapsulated by the top dielectric layers 26, while the bottom solder-mask 36 is formed underneath the bottom dielectric layers 28 to protect any bottom metal layer 32 (e.g., the third bottom metal layer 32-3) not being encapsulated by the bottom dielectric layers 28. The top solder-mask 34 is confined within the top dielectric layers 26 and does not extend across over any portion of each top hole 42. The bottom solder-mask 36 is confined within the bottom dielectric layers 28 and does not extend across over any portion of each bottom hole 44.

Note that each tooling-hole 18 extends vertically through the top dielectric layers 26, the core section 20/the corresponding sacrificial socket 22, and the bottom dielectric layers 28, and is a combination of a corresponding top hole 42, an inner perimeter of a corresponding sacrificial socket 22, and a corresponding bottom hole 44. The top dielectric layers 26, the corresponding sacrificial socket 22, and the bottom dielectric layers 28 are exposed in each tooling-hole 18. Since the top dielectric layers 26, the sacrificial sockets 22, and the bottom dielectric layers 28 are all relatively soft, there might be no, or negligible cracks introduced during forming the tooling-holes 18 (more details are described in the following paragraphs).

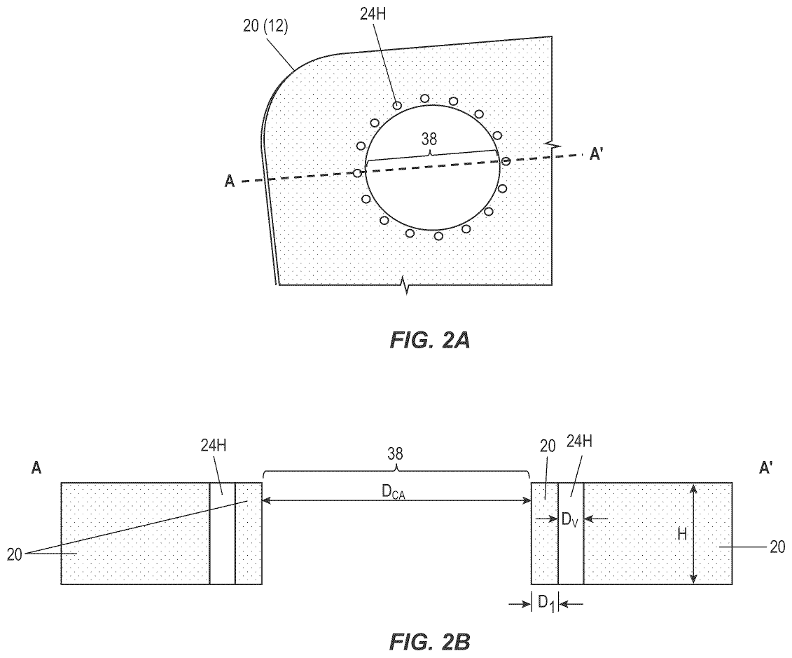

FIGS. 2A-7B show an exemplary fabricating process that illustrates steps to provide the rigid-core laminate 10 shown in FIGS. 1A-1B. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 2A-7B.

Initially, the core section 20 with the cavities 38 (only one cavity 38 is shown for simplicity) is provided as illustrated in FIGS. 2A and 2B. FIG. 2A shows a top view of the core section 20 within the partial border region 12, while FIG. 2B illustrates a cross-section view of the core section 20 along a dashed line A-A′ in FIG. 2A. In different applications, the cavities 38 may be formed within the border region of the core section 20, may be formed within the active region of the core section 20 (e.g., horizontally between the device-attached segments 16 or within certain device-attached segments 16, not shown), or may be formed in both the border region and the active region of the core section 20 (not shown). Herein, the core section 20 may also include multiple hollow protective vias 24H surrounding each cavity 38. Each hollow protective via 24H extends vertically through the core section 20 and has the diameter/diagonal D_{V} between 100 μm and 150 μm. The hollow protective vias 24H are configured to prevent cracks due to the formation of the corresponding cavity 38. Even if cracks occur, they can terminate on the extra surfaces provided by the hollow protective vias 24H and do not spread to the rest of the core section 20. Typically, each hollow protective via 24H and the corresponding cavity 38 have a distance D1 between 50 μm and 500 μm.

The core section 20 is a rigid section and may be formed of glass, silicon carbide, silicon, aluminum oxide, aluminum nitride, or other ceramic material, which has a modulus of at least 50 GPa. Due to different applications, the core section 20 may also be formed of other rigid materials (other than ceramic materials) with a modulus of at least 50 GPa for desired geometric/electronic/thermal performance. In addition, the core section 20 may have a height H between 300 μm and 400 μm, and each cavity 38 may have a diameter/diagonal D_{CA} between 0.2 mm and 5 mm or between 1.2 mm and 5 mm.

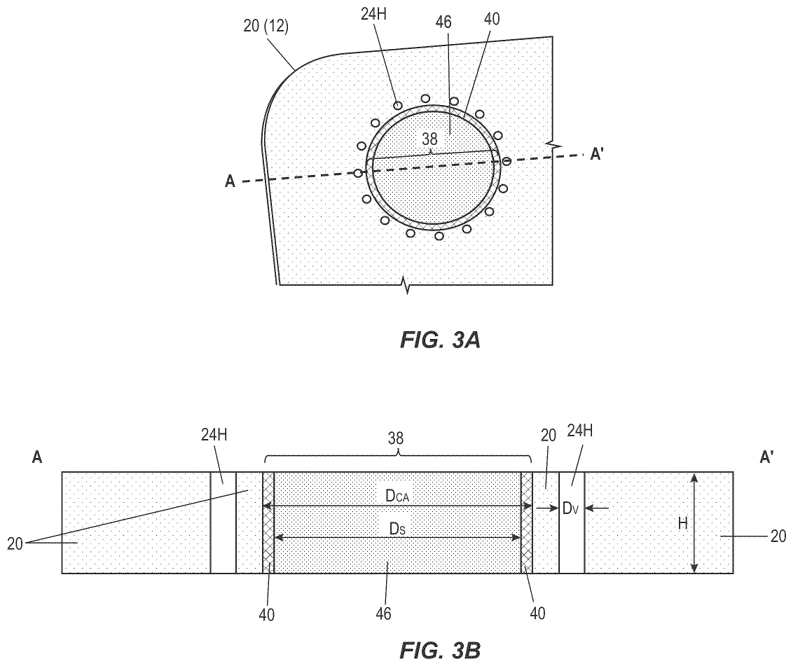

Next, a sacrificial plate 46 is embedded into each cavity 38 within the core section 20, as illustrated in FIGS. 3A and 3B. Typically, the sacrificial plate 46 has a same horizontal shape of a corresponding cavity 38, such as a circle, a square, a rectangle, an oval, a cushion, or any appropriate shape. The sacrificial plate 46 is embedded into the core section 20 using an existing embedding step for other components (not shown) embedded into the core section 20. Therefore, the sacrificial plate 46 does not require any additional embedding process. The sacrificial plate 46 has a diameter/diagonal D_{S} slightly smaller than the diameter/diagonal D_{CA} of a corresponding cavity 38 in order to be accommodated by the corresponding cavity 38. For a non-limiting example, the diameter/diagonal D_{S} of the sacrificial plate 46 is smaller than the diameter/diagonal D_{CA} of the corresponding cavity 38 by about 40 μm˜300 μm.

Once the sacrificial plate 46 is placed in the corresponding cavity 38, the potting material 40 is applied to fill the gap between the sacrificial plate 46 and its corresponding cavity 38. The potting material 40 may be an epoxy and may be applied by needle dispense, stencil printing, or three-dimensional (3D) printing. The potting material 40 is configured to bond each sacrificial plate 46 to the core section 20 within the corresponding cavity 38. After the potting material 40 is applied, a curing step (not shown) may be followed to harden the potting material 40. A curing temperature may be between 100° C.-300° C. depending on the material used for potting.

In some applications, each cavity 38 may have a same shape and same dimensions, and each sacrificial plate 46 may have a same shape and same dimensions and may be formed from a same material. In some applications, the cavities 38 may have different shapes and/or different dimensions, and the sacrificial plates 46 may have different shapes and/or different dimensions, and/or may be formed from different materials. The diameter/diagonal D_{S} of one sacrificial plate 46 may be between 0.2 mm and 5 mm or between 1.1 mm and 5 mm, and the height of one sacrificial plate 46 may be substantially the same as the height H of the core section 20. The sacrificial plate 46 may be formed of polymer, polymer and inorganic composite, or other relatively soft materials that can be readily drilled or milled and serve as a stress buffer between the core section 20 and subsequently inserted components (e.g., alignment pins) with a modulus of no more than 20 GPa.

FIGS. 4A and 4B show a metal plating step applied to the core section 20. Herein, the first top metal layer 30-1 is formed over the top surface of the core section 20, and the first bottom metal layer 32-1 is formed underneath the bottom surface of the core section 20. In some embodiments, the first top metal layer 30-1 may not extend over any portion of each cavity 38, and the first bottom metal layer 32-1 may not extend underneath any portion of each cavity 38. In some applications, the first top metal layer 30-1/the first bottom metal layer 32-1 may extend over each cavity 38 (not shown). In addition, by metal plating, each hollow protective via 24H is lined/plated with a metal material and converted into one protective via 24. The metal material used to line the hollow protective vias 24H is the same material used to form the first top metal layer 30-1 and the first bottom metal layer 32-1, such as copper, and gold.

In some applications, the metal plating step may be applied before the sacrificial plates 46 are embedded into the cavities 38 (not shown). In such a scenario, the metal material (e.g., the first top metal layer 30-1/the first bottom metal layer 32-1) may extend all the way to the edge of each cavity 38 and continuously cover an interior wall of each cavity 38. After the metal plating step is completed, the sacrificial plates 46 are embedded into the cavities 38 with the potting material 40 (as described above). Herein, the potting material 40 provides adhesion between the sacrificial plates 46 and the metal material. The first top metal layer 30-1 and the first bottom metal layer 32-1 do not extend horizontally over any portion of each sacrificial plate 46.

FIGS. 5A and 5B show a building up of the top dielectric layers 26, the bottom dielectric layers 28, other top metal layers 30 (e.g., the second and third top metal layers 30-2 and 30-3), and other bottom metal layers 32 (e.g., the second and third bottom metal layers 32-2 and 32-3) over or underneath the core section 20. In detail, the first top dielectric layer 26-1 extends across and is formed over the top surface of the core section 20 to cover each cavity 38 (i.e., cover the sacrificial plate 46 and the potting material 40) and encapsulate the first top metal layer 30-1. The first bottom dielectric layer 28-1 extends across and is formed underneath the bottom surface of the core section 20 to cover each cavity 38 (i.e., cover the sacrificial plate 46 and the potting material 40) and encapsulate the first bottom metal layer 32-1. The second top metal layer 30-2 is formed over the first top dielectric layer 26-1 and may or may not extend over each cavity 38. The second top dielectric layer 26-2 is formed over and extends across the first top dielectric layer 26-1, and encapsulates the second top metal layer 30-2. The second bottom metal layer 32-2 is formed underneath the first bottom dielectric layer 28-1 and may or may not extend underneath each cavity 38. The second bottom dielectric layer 28-2 is formed underneath and extends across the first bottom dielectric layer 28-1, and encapsulates the second bottom metal layer 32-2. The third top metal layer 30-3 is formed over the second top dielectric layer 26-2 and may or may not extend over each cavity 38. The third bottom metal layer 32-3 is formed underneath the second bottom dielectric layer 28-2 and may or may not extend underneath each cavity 38. For the purpose of this illustration, there are two top dielectric layers 26 and three top metal layers 30 formed over the core section 20, and two bottom dielectric layers 28 and three bottom metal layers 32 formed underneath the core section 20. In different applications, there might be fewer or more top dielectric layers 26, fewer or more top metal layers 30, fewer or more bottom dielectric layers 28, and/or fewer or more bottom metal layers 32.

Each top dielectric layer 26 may have a thickness between 0.2 μm and 60 μm or between 20 μm and 30 μm, and may be formed of a dielectric material, such as ABF epoxy, polyimide, or other dielectric material typically used in the microelectronics industry. Similarly, each bottom dielectric layer 28 may have a thickness between 0.5 μm and 60 μm or between 20 μm and 30 μm, and may be formed of a dielectric material, such as ABF epoxy, polyimide, or other dielectric material typically used in the microelectronics industry. Both the top dielectric layers 26 and the bottom dielectric layers 28 are relatively soft and may have a modulus of no more than 15 GPa. In addition, the second and third top metal layers 30-2 and 30-3 and the second and third bottom metal layers 32-2 and 32-3 might be formed of copper or gold. Furthermore, during the step of building up the top dielectric layers 26 and the bottom dielectric layers 28, each protective via 24 might be filled with the dielectric material(s) used to form the top dielectric layers 26 and the bottom dielectric layers 28.

Note that in addition to the sacrificial plate 46 needing to be easily and reliably drilled or milled to a stress buffer between the core section 20 and subsequently inserted components, the sacrificial plate 46 also provides mechanical support during the formation of the top and bottom dielectric layers 26 and 28 over the cavities 38. There will be a manufacturing challenge to add the top and bottom dielectric layers 26 and 28 if there are large unfilled cavities 38 existing in the core section 20.

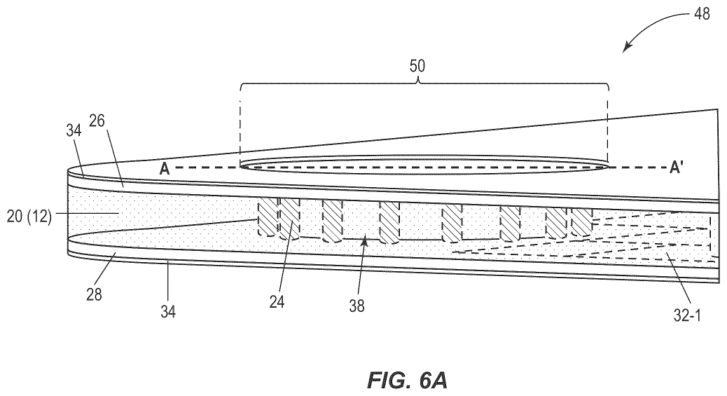

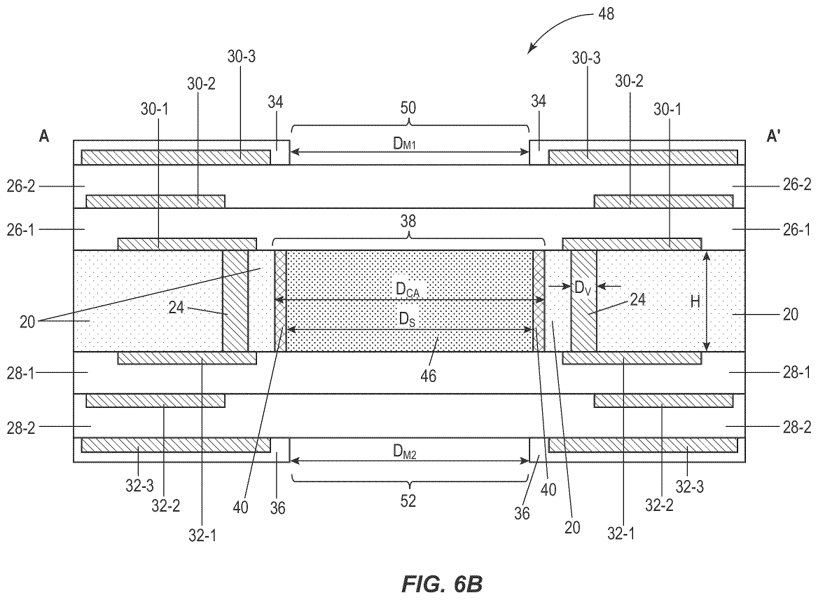

The top solder-mask 34 and the bottom solder-mask 36 are then applied to form a precursor laminate 48, as illustrated in FIGS. 6A and 6B. The top solder-mask 34 is formed over the second top dielectric layer 26-2 to fully cover the third top metal layer 30-3, while the bottom solder-mask 36 is formed underneath the second bottom dielectric layer 28-2 to fully cover the third bottom metal layer 32-3. Herein, the top solder-mask 34 includes multiple top mask holes 50 (only one top mask hole 50 is shown for simplicity) vertically aligned with the cavities 38, respectively, such that portions of the second top dielectric layer 26-2 are exposed through the top solder-mask 34. A diameter/diagonal D_{M1} of each top mask hole 50 might be the same, slightly smaller, or slightly larger than the diameter/diagonal D_{CA} of a corresponding cavity 38. The bottom solder-mask 36 includes multiple bottom mask holes 52 (only one bottom mask hole 52 is shown for simplicity) vertically aligned with the cavities 38, respectively, such that portions of the second bottom dielectric layer 28-2 are exposed through the bottom solder-mask 36. A diameter/diagonal D_{M2} of each bottom mask hole 52 might be the same, slightly smaller, or slightly larger than the diameter/diagonal D_{CA} of the corresponding cavity 38.

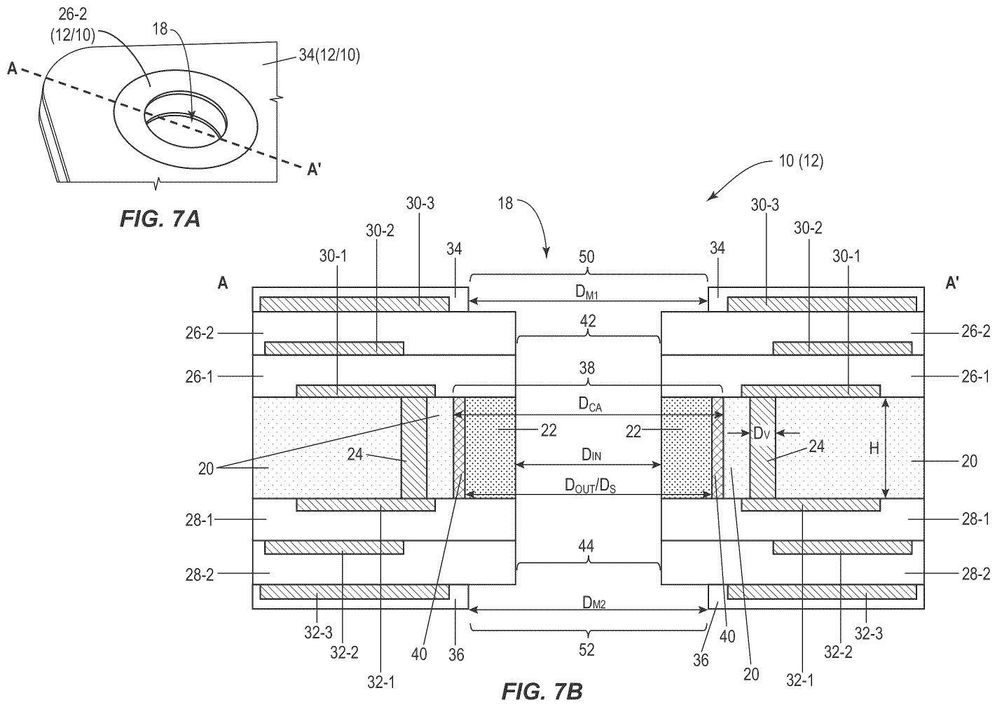

Lastly, the tooling-holes 18 are formed to complete the rigid-core laminate 10, as shown in FIG. 7A and 7B. Each tooling-hole 18 is formed where a corresponding sacrificial plate 46 is originally located and has a smaller horizontal size than the dimeter D_{S} of the corresponding sacrificial plate 46. The tooling-holes 18 are formed by drilling vertically through the precursor laminate 48 (i.e., drilling vertically through the top dielectric layers 26, the sacrificial plates 46, and the bottom dielectric layers 28, but not touching any portion of the core section 20) using a mechanical drill or laser machining. Herein, the top holes 42 are formed vertically through all of the top dielectric layers 26, the sacrificial plates 46 are converted into the sacrificial sockets 22, and the bottom holes 44 are formed vertically through all of the bottom dielectric layers 28. In some embodiments, each tooling-hole 18 has a smaller horizontal size than the dimeter D_{M1} of a corresponding top mask hole 50, and a smaller horizontal size than the dimeter DM2 of a corresponding bottom mask hole 52. As such, the drilling operation may not touch the top solder-mask 34 or the bottom solder-mask 36.

Since the top dielectric layers 26, the sacrificial plates 46, and the bottom dielectric layers 28 are all relatively soft (e.g., with a modulus of no more than 20 GPa), there might be no, or might be only negligible cracks introduced during the drilling step. Each tooling-hole 18 extends vertically through the top dielectric layers 26, vertically through the corresponding sacrificial socket 22, and the bottom dielectric layers 28, and is always confined within the corresponding sacrificial socket 22. As such, no drilling is performed directly through the core section 20, and no portion of the core section 20 is exposed in any tooling-hole 18. Typically, the horizontal size/shape of one tooling-hole 18 is constant along the vertical direction, which is the same as the inner perimeter of the corresponding sacrificial socket 22. The rigid-core laminate 10 may have a total height between 0.05 mm and 4 mm.

FIGS. 8-10B show an exemplary packaging process that illustrates steps to provide a package assembly formed based on the rigid-core laminate 10. Once the rigid-core laminate 10 is formed, one or more electrical devices 54 are attached to each device-attached segment 16 of the active region 14, as illustrated in FIG. 8. In this illustration, the tooling-holes 18 are located in the border region 12, and no electronic components are formed in the border region 12 or adjacent to the tooling-holes 18. In different applications, the tooling-holes 18 may be located in the active region 14, or located in both the border region 12 and the active region 14 (not shown).

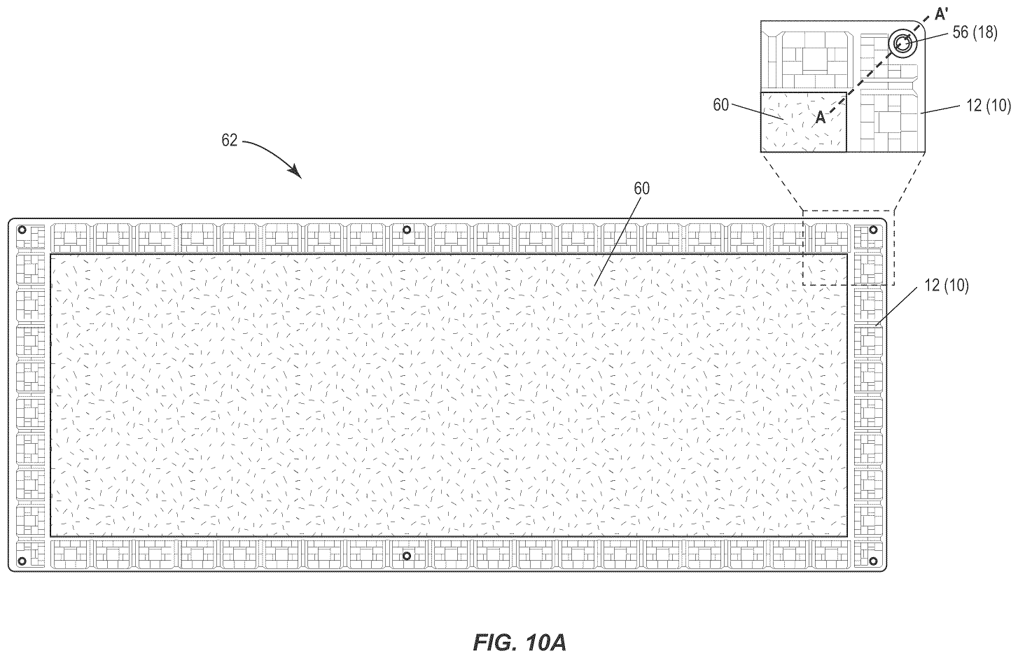

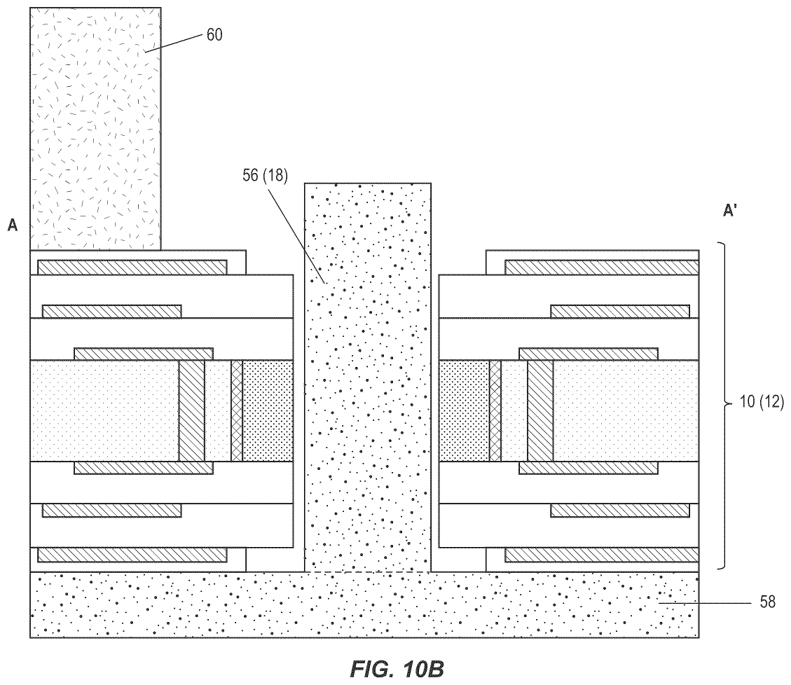

Next, alignment pins 56 are inserted into the tooling-holes 18, respectively, as shown in FIGS. 9A and 9B. Each alignment pin 56 has a height Hp larger than the height of the rigid-core laminate 10, and has a diameter/diagonal D_{P} slightly smaller than the horizontal size of a corresponding tooling-hole 18 (e.g., the dimeter D_{P} is about 80%-97% of the horizontal size of a corresponding tooling-hole 18). Note that only the top dielectric layers 26, one sacrificial socket 22, and the bottom dielectric layers 28, all of which are relatively soft, are exposed in a corresponding tooling-hole 18, which allows the tooling-holes 18 to receive the alignment pins 56 or any other kind of tooling without putting excess stress on the core section 20. In some embodiments, the alignment pins 56 may be formed on a connection tray 58. The connection tray 58 is placed underneath the rigid-core laminate 10, and each alignment pin 56 extends from the connection tray 58, upwards through the corresponding tooling-hole 18, and is vertically beyond the rigid-core laminate 10. Accordingly, the rigid-core laminate 10 can be secured to the connection tray 58, and the assembly or production equipment (e.g., used to form the electronic devices 54 and/or a mold compound 60 shown in FIGS. 10A, 10B) can locate the rigid-core laminate 10 more easily. Note that the tooling-holes 18 are only used for alignment/location purposes. None of the tooling-holes are metalized inside for any electronic functionality. The top dielectric layers 26, the corresponding sacrificial socket 22, and the bottom dielectric layers 28 are exposed in each tooling-hole 18. In some applications, the electrical devices 54 may be attached to the active region 14 after the rigid-core laminate 10 is secured to the connection tray 58 by inserting the alignment pins 56 into the tooling-holes 18.

After the alignment pins 56 are inserted into the corresponding tooling-holes 18, a mold compound 60 is formed over the rigid-core laminate 10 to form a package assembly 62, as illustrated in FIGS. 10A and 10B. Herein, the alignment pins 56 serve as “landmarks” for the rigid-core laminate 10 when the mold compound 60 is formed over the rigid-core laminate 10. In this way, the mold compound 60 can be applied at accurate locations and fully encapsulate each electrical device 54 (not shown) attached to the active region 14. In some embodiments, the mold compound 60 is formed by an overmolding step. A singulation step is then followed to separate the package assembly 62 into individual package modules (not shown). If the tooling-holes 18 and the alignment pins 56 are located in the active region 14, the alignment pins 56 may also serve as “landmarks” during the singulation of the package assembly 62.

The border region 12 of the rigid-core laminate 10 with the tooling-holes 18 is not included in the final package modules.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A rigid-core laminate comprising:
a core section that is formed of a first material with a first modulus of at least 50 GPa;
a plurality of sacrificial sockets embedded in the core section through a potting material, wherein the plurality of sacrificial sockets is formed of a second material with a second modulus that is smaller than the first modulus;
a plurality of top dielectric layers formed over a top surface of the core section and covering a top surface of each of the plurality of sacrificial sockets;
a plurality of bottom dielectric layers formed underneath a bottom surface of the core section and covering a bottom surface of each of the plurality of sacrificial sockets; and
a plurality of tooling-holes, each of which extends vertically through the plurality of top dielectric layers, a corresponding one of the plurality of sacrificial sockets within the core section, and the plurality of bottom dielectric layers, wherein no portion of the core section is exposed in any one of the plurality of tooling-holes.

2. The rigid-core laminate of claim 1 wherein the second modulus is no more than 20 GPa.

3. The rigid-core laminate of claim 1 wherein the first material is a ceramic material.

4. The rigid-core laminate of claim 3 wherein the second material is a polymer material or a polymer and inorganic composite.

5. The rigid-core laminate of claim 1 wherein:
the core section has a height between 10 μm and 2000 μm;
each of the plurality of top dielectric layers has a thickness between 0.2 μm and 60 μm; and
each of the plurality of bottom dielectric layers has a thickness between 0.2 μm and 60 μm.

6. The rigid-core laminate of claim 1 wherein a horizontal shape of each of the plurality of tooling-holes is constant along a vertical direction, which is identical to a shape of an inner perimeter of the corresponding one of the plurality of sacrificial sockets.

7. The rigid-core laminate of claim 1 wherein:
a shape of an inner perimeter of each of the plurality of sacrificial sockets is a circle, a square, a rectangle, an oval, or a cushion; and
a shape of an outer perimeter of each of the plurality of sacrificial sockets is a circle, a square, a rectangle, an oval, or a cushion.

8. The rigid-core laminate of claim 7 wherein a diameter of the inner perimeter of each of the plurality of sacrificial sockets is between 1 mm and 5 mm, and a diameter of the outer perimeter of each of the plurality of sacrificial sockets is between 1.1 mm and 5 mm.

9. The rigid-core laminate of claim 1 further includes a plurality of protective vias, wherein:
each of the plurality of sacrificial sockets is surrounded by certain ones of the plurality of protective vias; and
each of the plurality of protective vias has a diameter between 100 μm and 150 μm.

10. The rigid-core laminate of claim 1 further includes a plurality of top metal layers, and a plurality of bottom metal layers, wherein:
the plurality of top dielectric layers and the plurality of top metal layers are alternately formed over the top surface of the core section; and
the plurality of bottom dielectric layers and the plurality of bottom metal layers are alternately formed underneath the bottom surface of the core section.

11. The rigid-core laminate of claim 1 wherein the plurality of top dielectric layers and the plurality of bottom dielectric layers are formed of a dielectric material, which has a modulus of no more than 15 GPa.

12. The rigid-core laminate of claim 11 wherein the plurality of top dielectric layers and the plurality of bottom dielectric layers are formed of Ajinomoto build-up film (ABF) epoxy or polyimide.

13. The rigid-core laminate of claim 1 wherein the potting material is epoxy.

14. A method of fabricating a package assembly comprising forming a rigid-core laminate, wherein forming the rigid-core laminate comprises:
providing a core section with a plurality of cavities, wherein the core section is formed of a first material with a first modulus of at least 50 GPa;
embedding a sacrificial plate into each of the plurality of cavities, wherein the sacrificial plate is formed of a second material with a second modulus that is smaller than the first modulus;
applying a potting material to fill a gap between the sacrificial plate and a corresponding one of the plurality of cavities;
forming a plurality of top dielectric layers over a top surface of the core section and a top surface of the sacrificial plate, and forming a plurality of bottom dielectric layers underneath a bottom surface of the core section and a bottom surface of the sacrificial plate; and
forming a tooling-hole where a corresponding sacrificial plate is located, wherein:
the tooling-hole has a smaller horizontal size than a diameter of the corresponding sacrificial plate, and each sacrificial plate is converted into a corresponding sacrificial socket; and
the tooling-hole extends vertically through the plurality of top dielectric layers, the corresponding sacrificial socket, and the plurality of bottom dielectric layers.

15. The method of claim 14 wherein the core section further includes a plurality of hollow protective vias surrounding each of the plurality of cavities.

16. The method of claim 15 wherein forming the rigid-core laminate further comprises applying a metal plating step to the core section before forming the plurality of top dielectric layers and the plurality of bottom dielectric layers, wherein:
a first top metal layer is formed with a metal material over the top surface of the core section, a first bottom metal layer is formed with the metal material underneath the bottom surface of the core section; and
each of the plurality of hollow protective vias is filled with the metal material.

17. The method of claim 16 wherein the metal plating step is applied before embedding the sacrificial plate into each of the plurality of cavities, such that the metal material extends to cover an interior wall of each of the plurality of cavities.

18. The method of claim 16 wherein forming the rigid-core laminate further comprises forming a plurality of top metal layers and a plurality of bottom metal layers, wherein:
the plurality of top metal layers and the plurality of top dielectric layers are alternately formed over the top surface of the core section; and
the plurality of bottom metal layers and the plurality of bottom dielectric layers are alternately formed underneath the bottom surface of the core section.

19. The method of claim 14 wherein the second modulus is no more than 20 GPa.

20. The method of claim 14 wherein the first material is a ceramic material.

21. The method of claim 20 wherein the second material is a polymer material or a polymer and inorganic composite.

22. The method of claim 14 wherein the tooling-hole is formed by a mechanical drill or laser machining.

23. The method of claim 14 further comprising attaching one or more electrical devices to the rigid-core laminate, wherein:
in horizontal dimensions, the rigid-core laminate is divided into a border region and an active region, which is surrounded by the border region; and
the one or more electrical devices are located on a top surface of the rigid-core laminate and within the active region, while each sacrificial socket and the corresponding tooling-hole are located within the border region.

24. The method of claim 23 further comprising:
inserting one alignment pin into a corresponding tooling-hole, wherein each alignment pin has a height larger than a height of the rigid-core laminate and protrudes above the top surface of the rigid-core laminate; and
applying a mold compound over the rigid-core laminate using each alignment pin as a landmark, such that the one or more electrical devices are fully encapsulated by the mold compound.
